(19) United States
(12) Patent Application Publication
(10) Pub. No.: US 2025/0390150 A1
(43) Pub. Date: Dec. 25, 2025

(54) COMPUTING DEVICE CARD SYSTEM

(71) Applicant: Dell Products L.P., Round Rock, TX (US)

(72) Inventors: Kevin Warren Mundt, Austin, TX (US); Stephen Strickland, Foxborough, MA (US); Anand Nunna, Georgetown, TX (US)

(21) Appl. No.: 18/748,385

(22) Filed: Jun. 20, 2024

(51) Int. Cl. G06F 1/18; G06F 13/40; H05K 1/14

(52) U.S. Cl. CPC G06F 1/185; G06F 13/409; H05K 1/141; H05K 2201/10189

(57) ABSTRACT

A computing device card system includes a primary circuit board having an opposing primary circuit board top surface and bottom surface with an edge between them. A secondary circuit board includes an opposing secondary circuit board top surface and bottom surface with an edge between them. The secondary circuit board is connected to the primary circuit board bottom surface, and the secondary circuit board edge includes computing device connectors. The secondary circuit board extends from the primary circuit board edge such that the secondary circuit board edge is spaced apart from the primary circuit board edge. A bottom surface component envelope is defined adjacent the primary circuit board bottom surface and is based on the computing device connectors. Bottom surface component(s) extends from the primary circuit board bottom surface and are located within the bottom surface component envelope.

### BACKGROUND

The present disclosure relates generally to information handling systems, and more particularly to card systems used with information handling systems.

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems such as, for example, server devices and/or other computing devices known in the art, often have their functionality expanded using cards (e.g., “add-in” cards) that may be provided according to Peripheral Component Interconnect express (PCIe) Card ElectroMechanical (CEM) specifications, Pluggable Multipurpose Module (PMM) specifications, and/or other card specifications known in the art. Such card specifications define the dimensions of such cards, the card component envelopes that provide volume(s) adjacent the cards within which devices included on the card must be positioned in order to ensure that the cards will not interfere with any computing device components when they are provided in a computing device, as well as other features of the cards, which can raise issues.

For example, consider providing Data Processing Unit (DPU) functionality on a PMM card that is configured according to the PMM specifications discussed above. Such DPU functionality may require a memory subsystem, and such memory subsystems have conventionally been provided on DPU cards using memory devices mounted (e.g., soldered) to the DPU card (i.e., memory devices are provided “down” on DPU cards). As will be appreciated by one of skill in the art in possession of the present disclosure, the mounting of memory devices to the DPU card effectively prevents the modification of the memory capacity of that DPU card by a user. In order to address such issues, PMM cards have been designed to have Dual Inline Memory Module (DIMM) subsystems that include DIMM connectors mounted to the PMM card and DIMM devices that may be connected to/disconnected from the PMM card via the DIMM connectors. However, because of the height of such DIMM subsystems, PMM cards utilize the majority of their card component envelope for a “top” volume immediately adjacent a “top” surface of the PMM card (i.e., to which the DIMM connectors are mounted and the DIMM devices are connected), while providing a relatively limited “bottom” volume immediately adjacent a “bottom” surface of the PMM card that is opposite its “top” surface.

Furthermore, the processing system provided for DPU functionality discussed above requires a heat sink. In a PMM card configured with DPU functionality, that processing system may be provided centrally on the PMM card, with the DIMM subsystems provided on the PMM card on opposite sides of the processing system and adjacent to the “side” edges of the PMM card. However, such DIMM subsystem positioning will limit the size of the processing system, as well as the size of a heat sink that may be used with that processing system, and in many cases the thermal requirements of the processing system will call for a relatively larger heat sink that would span the width of the PMM card and thus extend into the volume occupied by the DIMM subsystems.

As discussed below, the inventors have recognized that one solution to such issues is to replace the DIMM subsystems discussed above with “low-profile” Compression Attached Memory Module (CAMM) subsystems provided by CAMM connectors mounted to the PMM card and CAMM devices that connect thereto, which one of skill in the art in possession of the present disclosure will appreciate would reduce the height of the memory subsystem on the PMM card and allows the relatively larger heat sinks discussed above to extend over the CAMM subsystems.

However, because of the size of CAMM devices, the use of CAMM subsystems on PMM cards in such a solution would require side-by-side positioning of a CAMM subsystem with the processing system, rather than having memory subsystems positioned on both sides of the processing system (as is available with the DIMM subsystems discussed above). One of skill in the art will appreciate how such a memory subsystem/processing system configuration would limit access by the processing system to the memory subsystem via one of its sides, thus reducing the number of communication channel between the processing system and the memory subsystem by half (i.e., relative to configuration in which memory subsystems are positioned on both sides of the processing system.) Such a memory subsystem/processing system configuration also reduces the number of memory devices that may be provided on the PMM card and thus increases the capacity and cost of memory devices that must be used with the PMM card to obtain the same memory capacity.

Furthermore, such a solution would also operate to “trap” the CAMM devices under the heat sink and require removal of the heat sink to access the CAMM devices, and because the CAMM devices are “taller” than the processing system, the heat sink for such a solution would need to be designed to engage the processing system, and either engage or clear the CAMM devices, which increases the costs of the heat sink.

Accordingly, it would be desirable to provide a computing device card system that addresses the issues discussed above.

### SUMMARY

According to one embodiment, an Information Handling System (IHS) includes a chassis; a card connector that is housed in the chassis; and a card that is connected to the card connector, wherein the card includes: a primary circuit board that includes a primary circuit board top surface, a primary circuit board bottom surface that is located opposite the primary circuit board from the primary circuit board top surface, and a primary circuit board edge that extends between the primary circuit board top surface and the primary circuit board bottom surface; a secondary circuit board that is connected to the primary circuit board bottom surface and that includes a secondary circuit board top surface, a secondary circuit board bottom surface that is located opposite the secondary circuit board from the secondary circuit board top surface, and a secondary circuit board edge that extends between the secondary circuit board top surface and the secondary circuit board bottom surface and includes a plurality of computing device connectors that engage the card connector, wherein the secondary circuit board extends from the primary circuit board edge such that the secondary circuit board edge is spaced apart from the primary circuit board edge; a bottom surface component envelope that is defined adjacent the primary circuit board bottom surface and that is based on the plurality of computing device connectors included on the secondary circuit board edge; and at least one bottom surface component that extends from the primary circuit board bottom surface and that is located within the bottom surface component envelope.

### BRIEF DESCRIPTION OF THE DRAWINGS

FIG. 1 is a schematic view illustrating an embodiment of an Information Handling System (IHS).

FIG. 2A is a perspective view illustrating an embodiment of a conventional card system.

FIG. 2B is a side view illustrating an embodiment of the conventional card system of FIG. 2A.

FIG. 3A is a side view illustrating an embodiment of a component on a card system exceeding a card component envelope.

FIG. 3B is a side view illustrating a close-up of the embodiment of FIG. 3A of the component on the card system exceeding the card component envelope.

FIG. 4A is a top perspective view illustrating an embodiment of a card system provided according to the teachings of the present disclosure.

FIG. 4B is a bottom perspective view illustrating an embodiment of the card system of FIG. 4A.

FIG. 4C is a top perspective view illustrating an embodiment of a card in the card system of FIGS. 4A and 4B.

FIG. 4D is a bottom perspective view illustrating an embodiment of the card of FIG. 4C.

FIG. 5A is a side view illustrating an embodiment of a component on the card system of FIGS. 4A and 4B positioned within a card component envelope.

FIG. 5B is a side view illustrating a close-up of the embodiment of FIG. 5A of the component on the card system of FIGS. 4A and 4B positioned within the card component envelope.

FIG. 6A is a side view illustrating an embodiment of a component on the card system of FIGS. 4A and 4B positioned within a card component envelope.

FIG. 6B is a side view illustrating a close-up of the embodiment of FIG. 6A of the component on the card system of FIGS. 5A and 5B positioned within the card component envelope.

FIG. 7 is a side view illustrating an embodiment of a card system that may be provided according to the teachings of the present disclosure.

FIG. 8 is a schematic view illustrating an embodiment of a computing device that may be utilized with the card system of the present disclosure.

FIG. 9 is a side view illustrating an embodiment of the card system of FIGS. 4A, 4B, 5A, and 5B being configured for connection to the computing device of FIG. 8.

FIG. 10 is a side view illustrating an embodiment of the card system of FIG. 9 connected to the computing device of FIG. 8.

FIG. 11 is a flow chart illustrating an embodiment of a method for providing a card component envelope for a card system used with a computing device.

### DETAILED DESCRIPTION

For purposes of this disclosure, an information handling system may include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (e.g., desktop or laptop), tablet computer, mobile device (e.g., personal digital assistant (PDA) or smart phone), server (e.g., blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

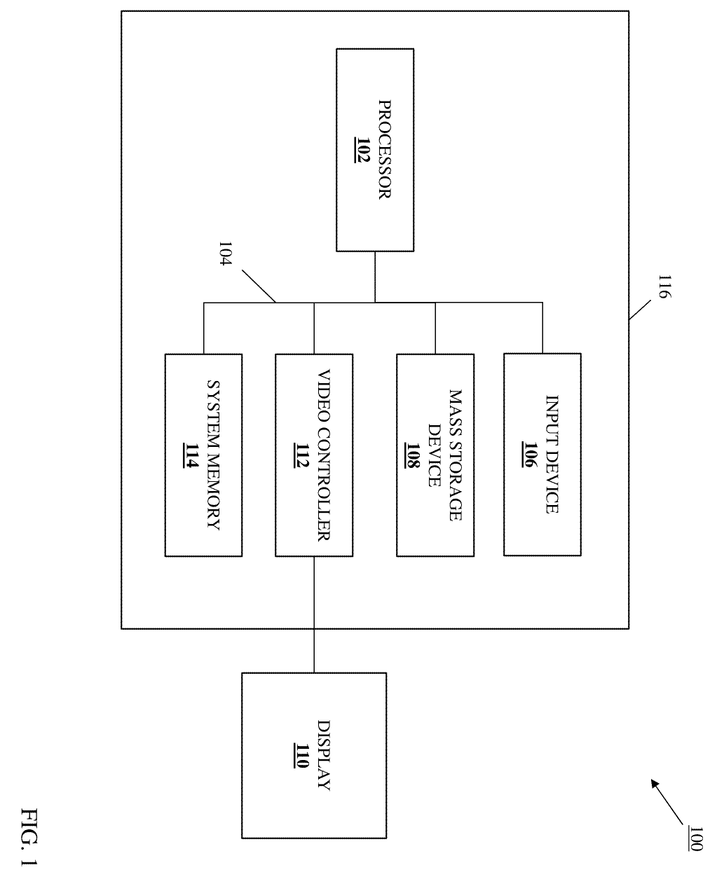

In one embodiment, IHS 100, FIG. 1, includes a processor 102, which is connected to a bus 104. Bus 104 serves as a connection between processor 102 and other components of IHS 100. An input device 106 is coupled to processor 102 to provide input to processor 102. Examples of input devices may include keyboards, touchscreens, pointing devices such as mouses, trackballs, and trackpads, and/or a variety of other input devices known in the art. Programs and data are stored on a mass storage device 108, which is coupled to processor 102. Examples of mass storage devices may include hard discs, optical disks, magneto-optical discs, solid-state storage devices, and/or a variety of other mass storage devices known in the art. IHS 100 further includes a display 110, which is coupled to processor 102 by a video controller 112. A system memory 114 is coupled to processor 102 to provide the processor with fast storage to facilitate execution of computer programs by processor 102. Examples of system memory may include random access memory (RAM) devices such as dynamic RAM (DRAM), synchronous DRAM (SDRAM), solid state memory devices, and/or a variety of other memory devices known in the art. In an embodiment, a chassis 116 houses some or all of the components of IHS 100. It should be understood that other buses and intermediate circuits can be deployed between the components described above and processor 102 to facilitate interconnection between the components and the processor 102.

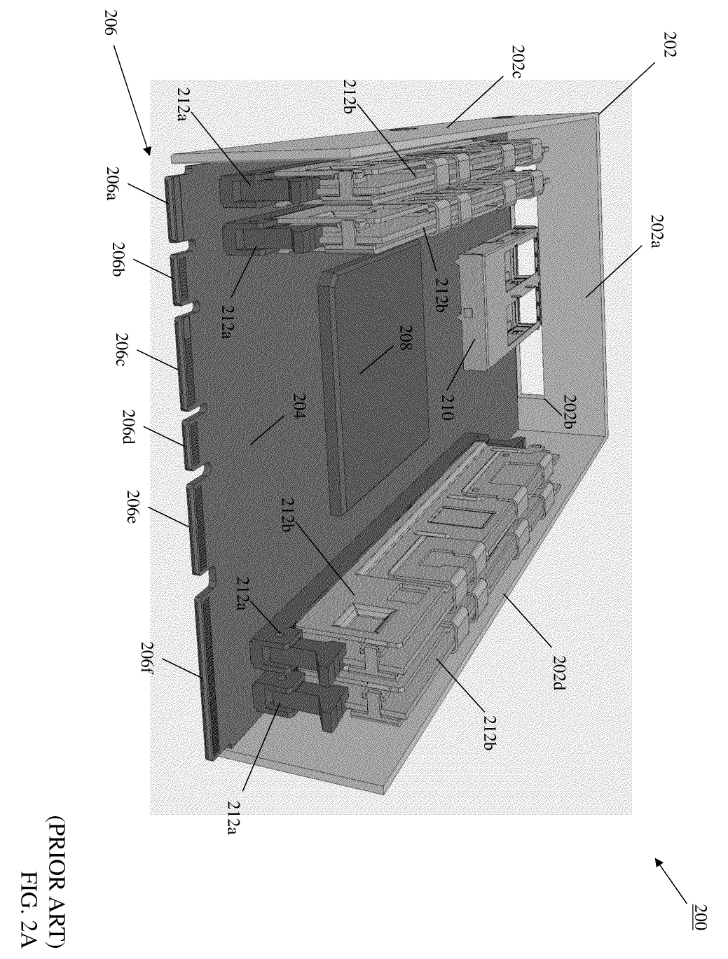

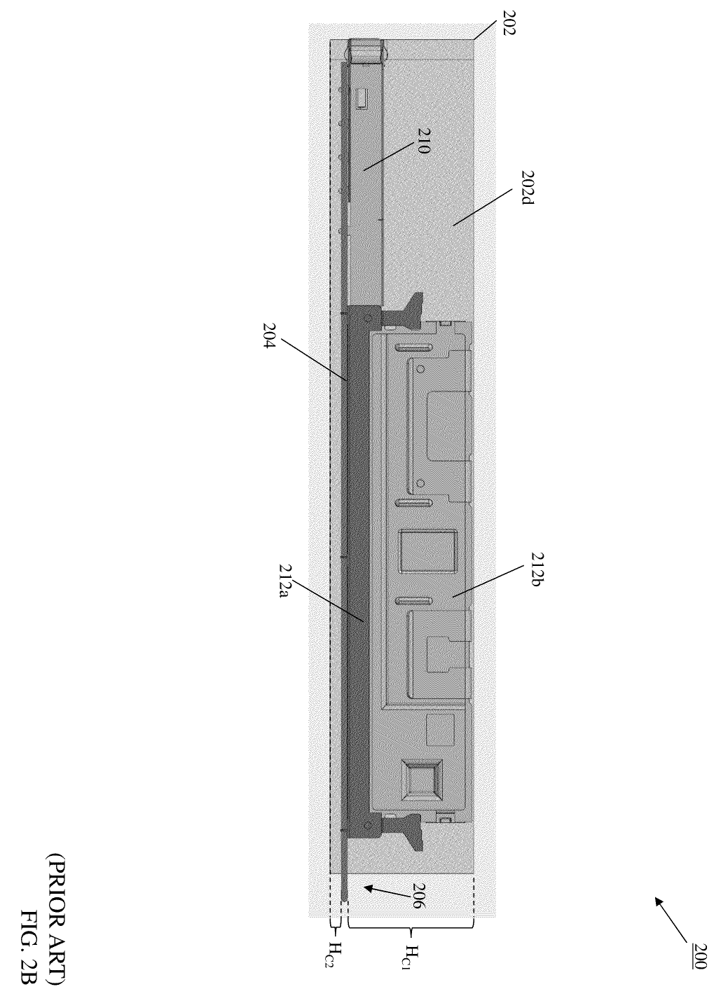

Referring now to FIGS. 2A and 2B, an embodiment of a conventional card system 200 is provided to illustrate some of the issues that are present in conventional card systems as described above. As will be appreciated by one of skill in the art in possession of the present disclosure, the conventional card system 200 in FIGS. 2A and 2B is illustrated and described as being provided by a conventional PMM card system according to PMM specifications, but similar issues exist with conventional PCIe CEM card systems and/or other conventional card systems known in the art. In the illustrated embodiment, the conventional card system 200 includes a chassis 202 that houses or otherwise supports the components of the conventional card system 200, only some of which are illustrated and described below. As illustrated, the chassis 202 includes a rear wall 202a defining a connector slot 202b, and a pair of side walls 202c and 202d that each extend approximately perpendicularly from the rear wall 202a and parallel to each other in a spaced-apart orientation to define a circuit board housing between the rear wall 202a and the side walls 202c and 202d. As will be appreciated by one of skill in the art in possession of the present disclosure, the chassis 202 will also include a bottom wall that extends between the rear wall 202a and the side walls 202c and 202d, but that bottom wall is not illustrated in the examples provided herein.

A circuit board 204 is positioned in the circuit board housing defined by the chassis 202 and connected to the bottom wall of the chassis 202, and is provided as per PMM specifications to include dimensions, a card component envelope (discussed in further detail below), components, and/or other PMM features that would be apparent to one of skill in the art in possession of the present disclosure. For example, the circuit board 204 includes a multi-connector edge 206 that extends from the circuit board housing and that is located opposite the circuit board 204 from the rear wall 202a of the chassis 202, and includes a plurality of connectors 206a, 206b, 206c, 206d, 206e, and 206f.

Continuing with the example of the conventional PMM component discussed above, the connector 206a may provide a 400W power connection; the connectors 206b, 206c, 206d, and 206e may provide a x16 PCIe connection, a sideband signal connection, and a 200 watt power connection; and the connector 206f may provide a x16 PCIe connection. As will be appreciated by one of skill in the art in possession of the present disclosure, the conventional card system 200 may be provided in a variety of different configurations. For example, a first configuration for a conventional PMM card system (also called a “1C” configuration) may provide a x4 PCIe connection and 200 watt power connection using the connector 206c, a second configuration for a conventional PMM card system (also called a “2C” configuration) may provide a x8 PCIe connection and 200 watt power connection using the connectors 206c and 206d, a third configuration for a conventional PMM card system (also called a “4C” configuration) may provide a x16 PCIe connection and 200 watt power connection using the connectors 206c/206d/206e, and a fourth configuration for a conventional PMM card system (also called a “4C+” configuration) may provide a x16 PCIe connection, an additional sideband connection, and 200 watt power connection using the connectors 206b/206c/206d/206e. Furthermore, one of skill in the art in possession of the present disclosure will appreciate how configurations providing a x32 PCIe connection and 600W power connection may be enabled using the connectors 206a/206b/206c/206d/206e/206f.

As discussed above, the conventional card system 200 may be configured to provide a variety of functionality, and the embodiment illustrated in FIGS. 2A and 2B provides an example of a DPU functionality configuration for a conventional PMM card system. As such, a processing system 208 (e.g., an Applicant Specific Integrated Circuit (ASIC) or other processing system known in the art) is mounted to the circuit board 204, and may be coupled to any or each of the connectors 206a-206f (e.g., via traces in the circuit board 204). Furthermore, a networking connector 210 (e.g., a Quad Small Form-factor Pluggable (QSFP) networking connector) is mounted to the circuit board 204 adjacent the connector slot 202b defined by the rear wall 202a of the chassis 202, and may be coupled to the processing system 208 and any or each of the connectors 206a-206f (e.g., via traces in the circuit board 204).

Further still, respective pairs of memory subsystems are mounted to the circuit board 204 on opposite sides of the processing system 208, and are coupled to the processing system 208 (e.g., via traces in the circuit board 204). In the illustrated example, the pairs of the memory subsystems are provided by a first pair of memory device connectors 212a mounted to the circuit board 204 between the processing system 208 and the side wall 202c of the chassis 202 with respective memory devices 212b (e.g., Registered Dual Inline Memory Module (RDIMM) devices in the illustrated example) connected thereto, and a second pair of memory device connectors 212a mounted to the circuit board 204 between the processing system 208 and the side wall 202d of the chassis 202 with respective memory devices 212b (e.g., RDIMM devices in the illustrated example) connected thereto.

As discussed above, the conventional card system 200 includes a card component envelope that provide volume(s) adjacent the circuit board 204 within which components included on the circuit board 204 must be positioned in order to ensure that the conventional card system 200 will not interfere with any computing device components when it is provided in a computing device. Furthermore, one of skill in the art in possession of the present disclosure will appreciate how the card component envelope for the conventional card system 200 is based on the multi-connector edge 206 and its connectors 206a-206f, as the connection of the multi-connector edge 206 to a card connector on a computing device will define the relative positioning of the conventional card system 200 in the computing device and the computing device components with which the conventional card system 200 should not interfere.

In the illustrated example, the card component envelope for the conventional card system 200 includes a volume “above” the circuit board 204 with a conventional height H_{C1}, and a volume “below” the circuit board 204 with a conventional height H_{C2}, and one of skill in the art in possession of the present disclosure will appreciate how the volumes for the card component envelope discussed above may extend to the rear wall 202a and side walls 202c and 202d of the chassis 202. To provide a specific example, for a conventional PMM card system, the conventional height H_{C1} may be 33.25 millimeters, and the conventional height H_{C2} may be 3.07 millimeters, although other card components envelope measurements will fall within the scope of the present disclosure as well.

As discussed above, conventional PMM card systems like that illustrated in FIGS. 2A and 2B were designed to allow the connection/disconnection of the memory devices 212a on the conventional PMM card system to enable modification of its memory capacity. As can be seen in FIG. 2B, the height of the memory subsystems provided by the memory device connectors 212a and the memory devices 212b connected thereto require the conventional card system 200 to utilize the majority of its card component envelope for the volume “above” the circuit board 204 (i.e., with the conventional height H_{C1}), while providing a relatively limited volume “below” the circuit board 204 (i.e., with the conventional height H_{C2}). Furthermore, the configuration of the memory subsystems and processing system 208 illustrated in FIGS. 2A and 2B limits the size of the processing system 208. Further still, in situations in which the processing system 208 requires a heat sink, the memory subsystems will limit the size of that heat sink, and in many cases the thermal requirements of the processing system 208 (e.g., in DPU applications) will call for a relatively larger heat sink that would span the width of the circuit board 204 (i.e., between the side walls 202c and 202d of the chassis 202) and thus extend into the volume occupied by the memory subsystems.

The inventors have recognized that one solution to such issues is to replace the memory subsystems having the memory device connectors 212a and memory devices 212b (e.g., the RDIMM devices) with “low-profile” Compression Attached Memory Module (CAMM) subsystems provided by CAMM connectors and CAMM devices that connect thereto, which one of skill in the art in possession of the present disclosure will appreciate would reduce the height of the memory subsystem on the circuit board 204 in the conventional card system 200 and allow the relatively larger heat sinks discussed above to extend over the CAMM subsystems.

However, because of the size of CAMM devices, the use of CAMM subsystems on the circuit board 204 in the conventional card system 200 as described above would require side-by-side positioning with the processing system 208 (i.e., with the processing system 208 located immediately adjacent the side wall 202d of the chassis 202, and the CAMM subsystem located between the processing system 208 and the side wall 202c of the chassis 202, rather than having memory subsystems positioned on both sides of the processing system 208 as illustrated in FIGS. 2A and 2B) . One of skill in the art will appreciate how such a memory subsystem/processing system configuration would limit access by the processing system to the memory subsystem via one of its sides, thus reducing the number of communication channel between the processing system and the memory subsystem by half (i.e., relative to configuration in which memory subsystems are positioned on both sides of the processing system.) Such a memory subsystem/processing system configuration also reduces the number of memory devices that may be provided on the conventional card system 200 and thus increases the capacity and cost of memory devices that must be used with the conventional card system 200 to obtain the same memory capacity as is provided in FIGS. 2A and 2B. Furthermore, such a solution would operate to “trap” the CAMM devices under the heat sink and require removal of the heat sink to access the CAMM devices, and because the CAMM devices are “taller” than the processing system 208, the heat sink for such a solution would need to be designed to engage the processing system 208, and either engage or clear the CAMM devices, which increases the costs of the heat sink.

As discussed below, the computing device card system of the present disclosure addresses the issues discussed above by providing the CAMM devices on a “bottom” surface of a circuit board in the computing device card system that is opposite a “top” surface of that circuit board to which a processing system is mounted, which does not limit the size of the processing system or the width of the heat sink that may be used in the computing device card system, allows access to the CAMM devices when the heat sink is installed, provides better thermal efficiency (e.g., airflow) for the CAMM devices, and/or provide other benefits that would be apparent to one of skill in the art in possession of the present disclosure.

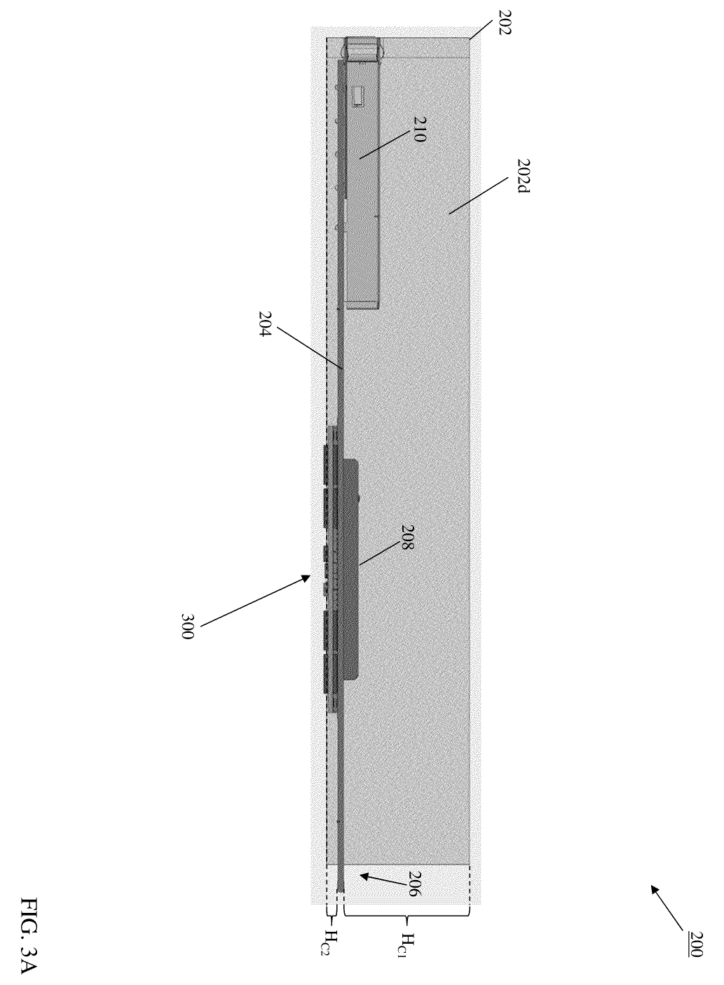

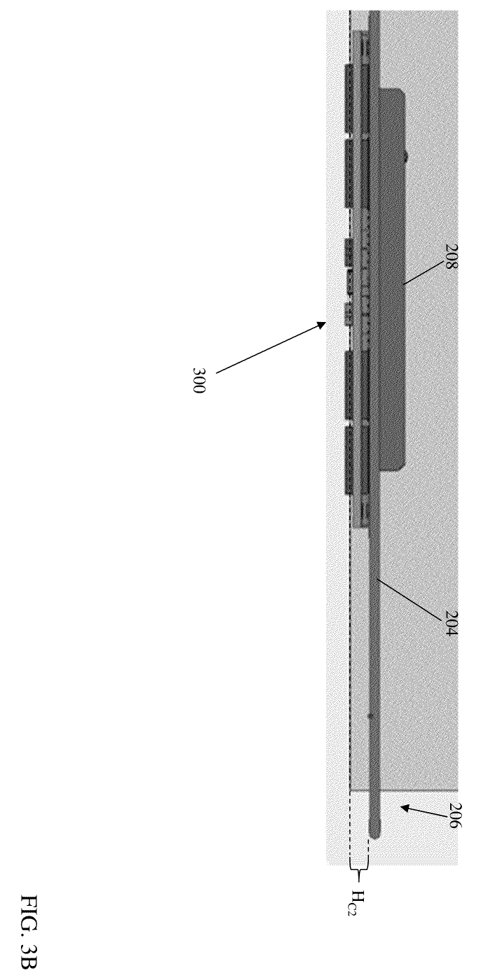

However, the positioning of the CAMM devices on the circuit board of a PMM card system in such a manner presents issues as well. For example, with reference to FIGS. 3A and 3B, the conventional card system 200 discussed above with reference to FIGS. 2A and 2B is illustrated with the memory subsystems provided by the memory device connectors 212a and the memory devices 212b removed, and CAMM subsystem(s) 300 mounted to a “bottom” surface of the circuit board 204 that is opposite the circuit board 204 from a “top” surface to which the processing system 208 is mounted. As can be seen in FIGS. 3A and 3B, if the CAMM subsystems 300 are mounted to a “bottom” surface of the circuit board 204, the CAMM subsystems 300 will extend out of the card component envelope provided by the volume “below” the circuit board 204 (i.e., with the conventional height H_{C2}) and thus will not fit in the chassis 202 when the bottom wall is present. To provide a specific example, using a 1 millimeter CAMM connector to connect a CAMM device to the circuit board 204, the CAMM subsystem extended 0.63 millimeters past the 3.07 millimeter conventional height H_{C2} provided by the card component envelope discussed above.

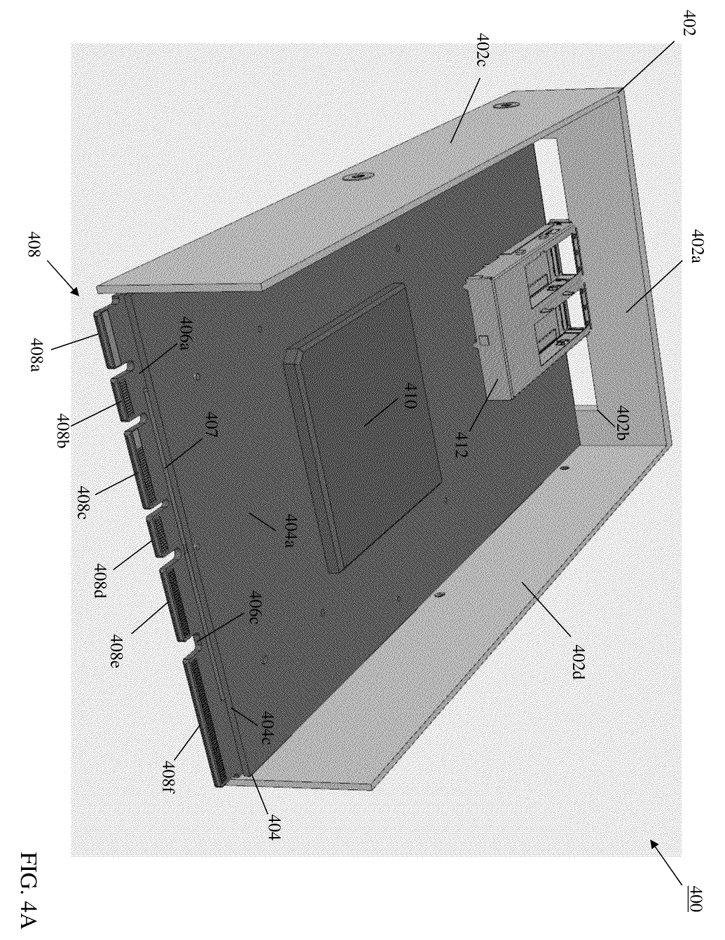

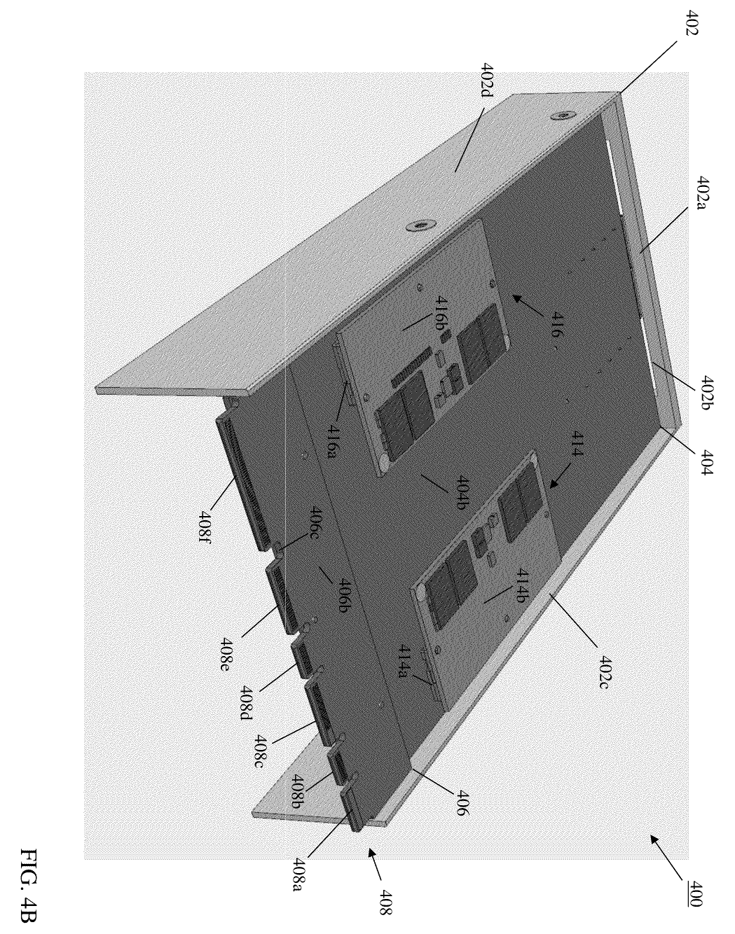

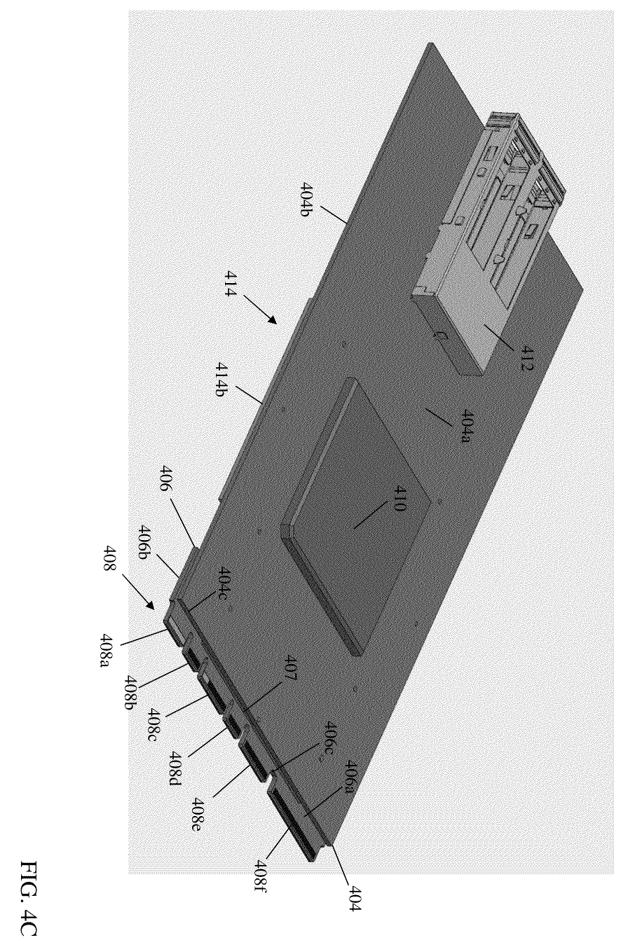

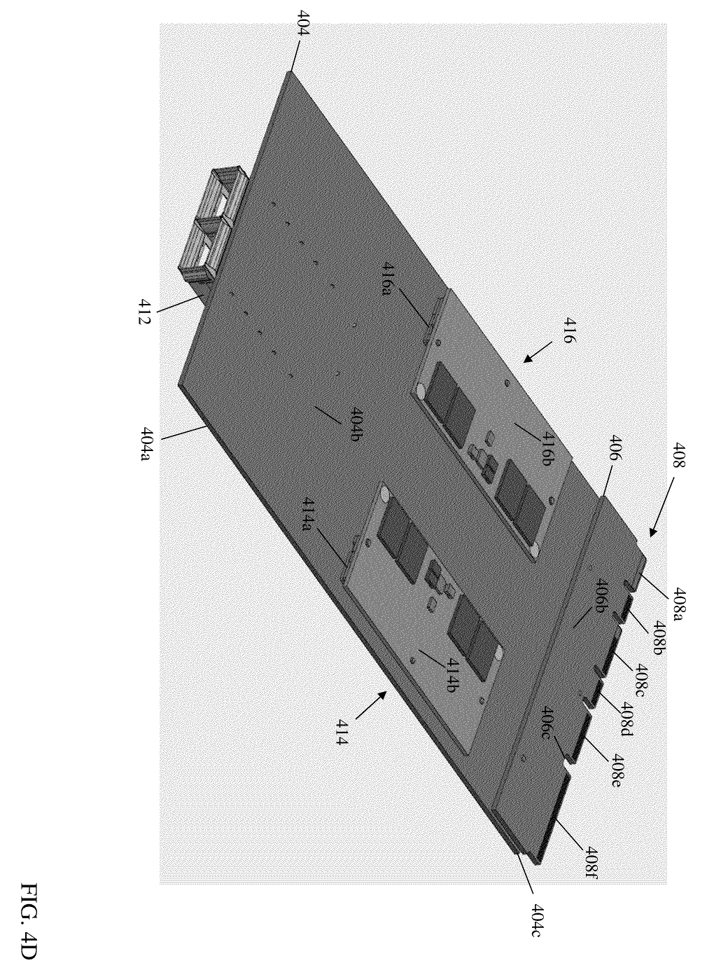

Referring now to FIGS. 4A, 4B, 4C, and 4D, an embodiment of computing device card system 400 is illustrated that may be provided according to the teachings of the present disclosure to address the issues discussed above. As will be appreciated by one of skill in the art in possession of the present disclosure, the computing device card system 400 in FIGS. 4A-4D is illustrated and described as being provided according to some PMM specifications with modifications that will be apparent to one of skill in the art in possession of the present disclosure, but one of skill in the art in possession of the present disclosure will appreciate how PCIe CEM card systems and/or other card systems known in the art may be modified in a similar manner to provide the benefits of the present disclosure as well. In the illustrated embodiment, the computing device card system 400 includes a chassis 402 that houses or otherwise supports the components of the computing device card system 400, only some of which are illustrated and described below. As illustrated, the chassis 402 may include a rear wall 402a defining a connector slot 402b, and a pair of side walls 402c and 402d that each extend approximately perpendicularly from the rear wall 402a and parallel to each other in a spaced-apart orientation to define a circuit board housing between the rear wall 402a and the side walls 402c and 402d. As will be appreciated by one of skill in the art in possession of the present disclosure, the chassis 402 will also include a bottom wall that extends between the rear wall 402a and the side walls 402c and 402d, but that bottom wall is not illustrated in the examples provided herein.

A primary circuit board 404 is positioned in the circuit board housing and connected to the bottom wall of the chassis 402, and may be provided as per at least some PMM specifications to include dimensions, components, and/or other PMM features that would be apparent to one of skill in the art in possession of the present disclosure. The primary circuit board 404 includes a primary circuit board top surface 404a, a primary circuit board bottom surface 404b that is located opposite the primary circuit board 404 from the primary circuit board top surface 404a, and a primary circuit board edge 404c that extends between the primary circuit board top surface 404a and the primary circuit board bottom surface 404b and that is located opposite the primary circuit board 404 from the rear wall 402a of the chassis 402.

In the illustrated embodiment, the secondary circuit board 406 is connected via a circuit board connection subsystem 407 (discussed in further detail below) to the primary circuit board bottom surface 404b of the primary circuit board 404, and includes a secondary circuit board top surface 406a that faces the primary circuit board bottom surface 404b, a secondary circuit board bottom surface 406b that is located opposite the secondary circuit board 406 from the secondary circuit board top surface 406a, and a secondary circuit board edge 406c that extends between the secondary circuit board top surface 406a and the secondary circuit board bottom surface 406b. As can be seen in FIGS. 4A-4D, the secondary circuit board 406 extends past the primary circuit board edge 404c such that the secondary circuit board edge 406c is spaced apart from the primary circuit board edge 404c.

The secondary circuit board 406 includes a multi-connector edge 408 that extends from the secondary circuit board edge 406c and the circuit board housing, and that includes a plurality of connectors 408a, 408b, 408c, 408d, 408e, and 408f. As will be appreciated by one of skill in the art in possession of the present disclosure, in the illustrated embodiment the connectors 408a-408f may be provided according to PMM specifications, and thus the connector 408a may provide a 400W power connection; the connectors 408b, 408c, 408d, and 408e may provide a x16 PCIe connection, a sideband signal connection, and a 200 watt power connection; and the connector 408f may provide a x16 PCIe connection. As will be appreciated by one of skill in the art in possession of the present disclosure, the computing device card system 400 may be provided in a variety of different configurations similarly as described above for the conventional card system 200.

Similarly as discussed above for the conventional card system 200, the computing device card system 400 may be configured to provide a variety of functionality, and the embodiment illustrated in FIGS. 4A-4D provides an example of a DPU functionality configuration for the computing device card system 400. As such, a processing system 410 (e.g., an ASIC or other processing system known in the art) is mounted to the primary circuit board top surface 404a of the primary circuit board 404, and may be coupled to any or each of the connectors 408a-408f (e.g., via traces in the primary circuit board 404 and the secondary circuit board 406, and via the circuit board connection subsystem 407). Furthermore, a networking connector 412 (e.g., a QSFP networking connector) is mounted to the primary circuit board top surface 404a of the primary circuit board 404 adjacent the connector slot 402b defined by the rear wall 402a of the chassis 402, and may be coupled to the processing system 410 (e.g., via traces in the primary circuit board 404) and any or each of the connectors 408a-408f (e.g., via traces in the primary circuit board 404 and the secondary circuit board 406, and via the circuit board connection subsystem 407).

Further still, a pair memory subsystems 414 and 416 are provided on opposite sides of the primary circuit board 404 and adjacent the side walls 402c and 402d, respectively, of the chassis 402, and are coupled to the processing system 410 (e.g., via traces in the primary circuit board 404). In the illustrated example, the memory subsystems 414 and 416 are provided by a pair of memory device connectors 414a and 416a, respectively, that are mounted to the primary circuit board bottom surface 404b of the primary circuit board 404, with respective memory devices 414b and 416b connected thereto. As will be appreciated by one of skill in the art in possession of the present disclosure, in the examples illustrated and described below, the memory subsystems 414 and 416 are provided by CAMM subsystems, although other memory subsystems and/or other components are envisioned as falling within the scope of the present disclosure as well. However, while a specific computing device card system 400 has been illustrated and described, one of skill in the art in possession of the present disclosure will recognize that computing device card systems (or other devices operating according to the teachings of the present disclosure in a manner similar to that described below for the computing device card system 400) may include a variety of components and/or component configurations for providing conventional card system functionality, as well as the computing device card system functionality discussed below, while remaining within the scope of the present disclosure as well.

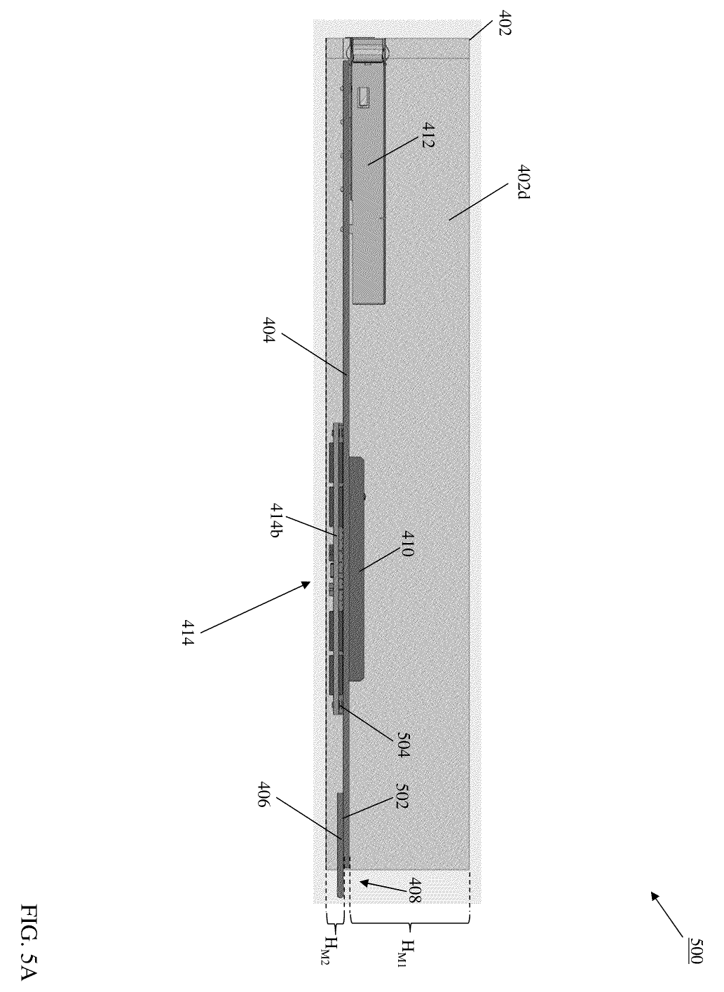

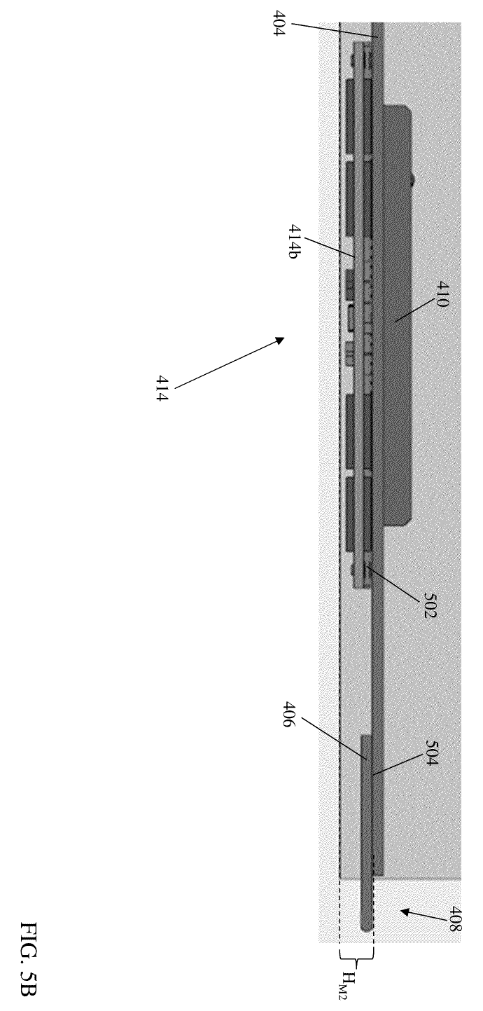

Referring now to FIGS. 5A and 5B, a computing device card system 500 is illustrated that provides an embodiment of the computing device card system 400 discussed above with reference to FIGS. 4A-4D, with similar elements provided with similar element numbers. As will be appreciated by one of skill in the art in possession of the present disclosure, the embodiment illustrated in FIGS. 5A and 5B provides a specific example of the connection of the secondary circuit board 406 and the memory subsystem 414 to the primary circuit board 404. In this specific example, the circuit board connection subsystem 407 discussed above with reference to FIGS. 4A-4D is provided by a circuit board direct connection subsystem 502 that directly connects the secondary circuit board 406 to the primary circuit board 404 using soldering techniques (e.g., Ball Grid Array (BGA) soldering techniques, hot bar solder techniques, etc.), castellations, and/or other circuit board direct-connect techniques that one of skill in the art in possession of the present disclosure would appreciate position the primary circuit board bottom surface 404b and the secondary circuit board top surface 406a immediately adjacent (and sometime in engagement with) each other.

Continuing with this specific example, the memory device connector 414a on the memory subsystem 414 (and the memory device connector 416a on the memory subsystem 416, not visible in FIGS. 5A and 5B) discussed above with reference to FIGS. 4A-4D may be provided by respective 1.85 millimeter CAMM connectors 504. As can be seen in FIGS. 5A and 5B, the card component envelope for the computing device card system 500 includes a volume “above” the primary circuit board top surface 404 of the primary circuit board 404 with a modified height H_{1M}, and a volume “below” the primary circuit board bottom surface 404b of the primary circuit board 404 with a modified height H_{M2}, and one of skill in the art in possession of the present disclosure will appreciate how the volumes for the card component envelope discussed above may extend to the rear wall 202a and side walls 202c and 202d of the chassis 202. Furthermore, one of skill in the art in possession of the present disclosure will appreciate how the card component envelope for the computing device card system 500 is based on the multi-connector edge 408 and its connectors 408a-408f, as the connection of the multi-connector edge 408 to a card connector on a computing device (discussed in further detail below) will define the relative positioning of the computing device card system 500 in the computing device and the computing device components with which the computing device card system 500 should not interfere.

As will be appreciated by one of skill in the art in possession of the present disclosure, the connection of the secondary circuit board 406 to the primary circuit board bottom surface 404b of the primary circuit board 404 operates to offset the computing device connection point of the computing device card system 500 to a second plane that is below a first plane defined by the primary circuit board 404, thus increasing the volume of the card component envelope “below” the primary circuit board bottom surface 404b of the primary circuit board 404 (i.e., the modified height H_{M2} illustrated in FIGS. 5A and 5B is greater than the conventional height H_{C2} illustrated in FIGS. 2A and 2B). As such, the memory subsystem 414 (and the memory subsystem 416, not visible in FIGS. 5A and 5B) mounted to the primary circuit board bottom surface 404b fits within the volume of the card component envelope “below” the primary circuit board bottom surface 404b of the primary circuit board 404.

In order for the computing device card system 500 to maintain the same total card component envelope height as the conventional card system 200 (i.e., H_{M1} + H_{M2} = H_{C1} + H_{C2}), the connection of the secondary circuit board 406 to the primary circuit board bottom surface 404b of the primary circuit board 404 will operate to reduce the volume of the card component envelope “above” the primary circuit board top surface 404a of the primary circuit board 404 (i.e., the modified height H_{M1} illustrated in FIGS. 5A and 5B is less than the conventional height H_{C1} illustrated in FIGS. 2A and 2B). However, one of skill in the art in possession of the present disclosure will appreciate how the positioning of memory subsystems (or other devices) on the “bottom” of the computing device card system 500 provides substantial benefits relative to the loss of heat sink height.

Thus, one of skill in the art in possession of the present disclosure will recognize that, in some embodiments, the dimensions of the computing device card system 500 including its card component envelope may be the same as the dimensions of the conventional card system 200 including its card component envelope, but with the computing device card system 500 providing a larger volume card component envelope “below” its primary circuit board 404 (i.e., relative to the volume of the card component envelope “below” the circuit board 204 on the conventional card system 200).

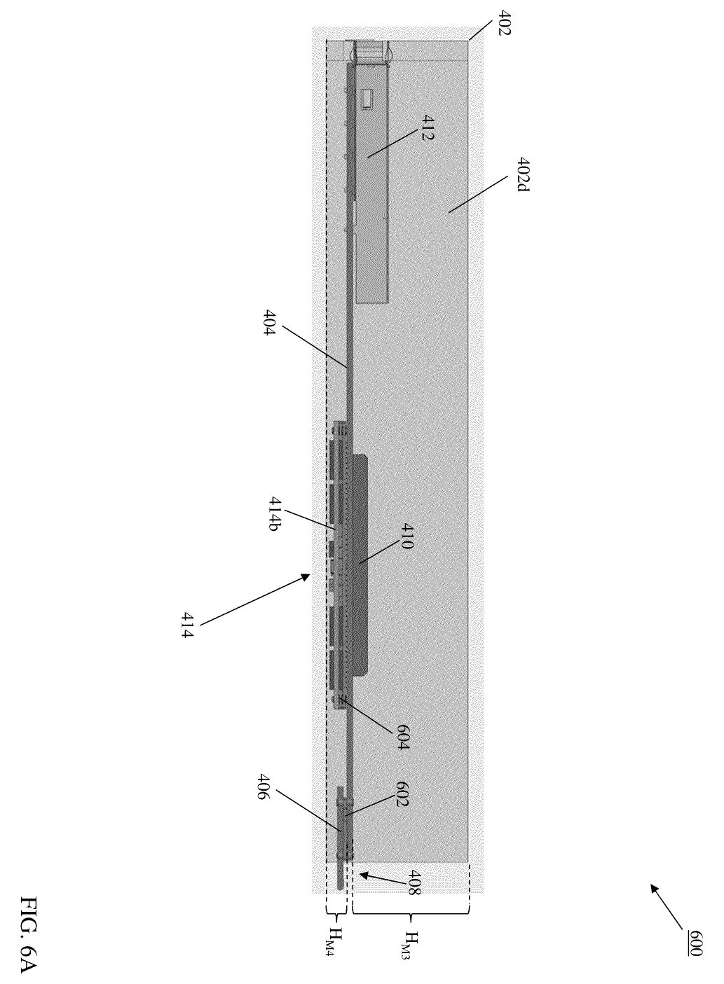

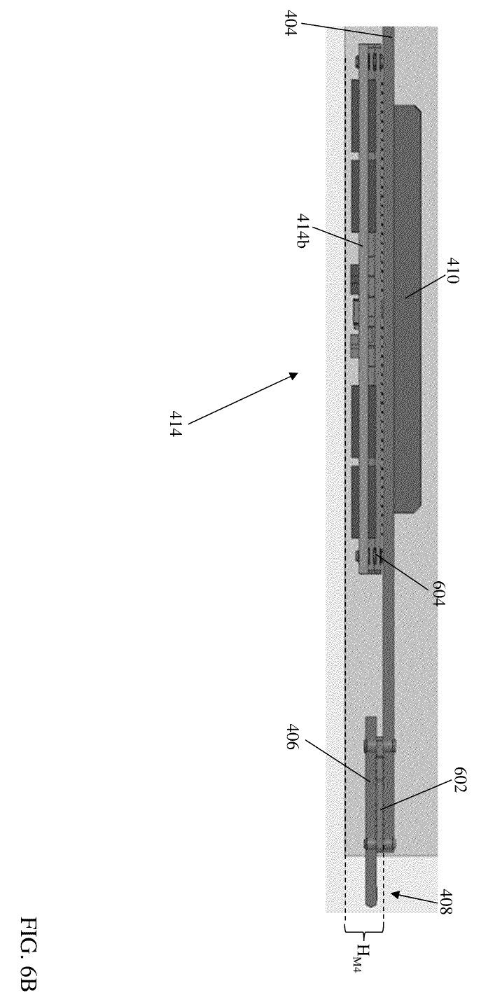

Referring now to FIGS. 6A and 6B, a computing device card system 600 is illustrated that provides an embodiment of the computing device card system 400 discussed above with reference to FIGS. 4A-4D, with similar elements provided with similar element numbers. As will be appreciated by one of skill in the art in possession of the present disclosure, the embodiment illustrated in FIGS. 6A and 6B provides another specific example of the connection of the secondary circuit board 406 and the memory subsystem 414 to the primary circuit board 404. In this specific example, the circuit board connection subsystem 407 discussed above with reference to FIGS. 4A-4D is provided by a circuit board connector subsystem 602 that may be provided by a 1.85 millimeter Land Grid Array (LGA) compression connector that is connected to each of the primary circuit board bottom surface 404b of the primary circuit board 404 and the secondary circuit boar top surface 406a of the secondary circuit board 406, and/or using other circuit board connectors that one of skill in the art in possession of the present disclosure would appreciate position the primary circuit board bottom surface 404b and the secondary circuit board top surface 406a spaced-apart and adjacent (e.g., facing) each other.

Continuing with this specific example, the memory device connector 414a on the memory subsystem 414 (and the memory device connector 416a on the memory subsystem 416, not visible in FIGS. 6A and 6B) discussed above with reference to FIGS. 4A-4D are provided by respective 2.85 millimeter CAMM connectors 604. As can be seen in FIGS. 6A and 6B, the card component envelope for the computing device card system 600 includes a volume “above” the primary circuit board top surface 404 of the primary circuit board 404 with a modified height H_{M3}, and a volume “below” the primary circuit board bottom surface 404b of the primary circuit board 404 with a modified height H_{M4}, and one of skill in the art in possession of the present disclosure will appreciate how the volumes for the card component envelope discussed above may extend to the rear wall 202a and side walls 202c and 202d of the chassis 202. Furthermore, one of skill in the art in possession of the present disclosure will appreciate how the card component envelope for the computing device card system 600 is based on the multi-connector edge 408 and its connectors 408a-408f, as the connection of the multi-connector edge 408 to a card connector on a computing device (discussed in further detail below) will define the relative positioning of the computing device card system 600 in the computing device and the computing device components with which the computing device card system 600 should not interfere.

As will be appreciated by one of skill in the art in possession of the present disclosure, the connection of the secondary circuit board 406 to the primary circuit board bottom surface 404b of the primary circuit board 404 operates to offset the computing device connection point of the computing device card system 600 to a second plane that is below a first plane defined by the primary circuit board 404, thus increasing the volume of the card component envelope “below” the primary circuit board bottom surface 404b of the primary circuit board 404 (i.e., the modified height H_{M4} illustrated in FIGS. 6A and 6B is greater than the conventional height H_{C2} illustrated in FIGS. 2A and 2B, and the modified height H_{M2} illustrated in FIGS. 5A and 5B). As such, the memory subsystem 414 (and the memory subsystem 416, not visible in FIGS. 5A and 5B) mounted to the primary circuit board bottom surface 404b fits within the volume of the card component envelope “below” the primary circuit board bottom surface 404b of the primary circuit board 404.

In order for the computing device card system 600 to maintain the same total card component envelope height as the conventional card system 200 (i.e., H_{M3} + H_{M4} = H_{C1} + H_{C2}), the connection of the secondary circuit board 406 to the primary circuit board bottom surface 404b of the primary circuit board 404 will operate to reduce the volume of the card component envelope “above” the primary circuit board top surface 404a of the primary circuit board 404 (i.e., the modified height H_{M3} illustrated in FIGS. 6A and 6B is less than the conventional height H_{C1} illustrated in FIGS. 2A and 2B). However, one of skill in the art in possession of the present disclosure will appreciate how the positioning of memory subsystems (or other devices) on the “bottom” of the computing device card system 600 provides substantial benefits relative to the loss of heat sink height.

Thus, one of skill in the art in possession of the present disclosure will recognize that, in some embodiments, the dimensions of the computing device card system 600 including its card component envelope may be the same as the dimensions of the conventional card system 200 including its card component envelope (and the computing device card system 500 including its card component envelope), but with the computing device card system 600 providing a larger volume card component envelope “below” its primary circuit board 404 (i.e., relative to the volume of the card component envelope “below” the circuit board 204 on the conventional card system 200, and relative to the volume of the card component envelope “below” the circuit board 404 on the computing device card system 500).

As such, the direct connection of the secondary circuit board 406 to the primary circuit board bottom surface 404a of the primary circuit board 404 increases the height of the volume of the card component envelope “below” the primary circuit board bottom surface 404a by an amount that is sufficient to allow memory devices (i.e., CAMM devices in the illustrated embodiments) to be provided on the primary circuit board bottom surface 404a of the primary circuit board 404 using relatively low-profile memory device connectors (i.e., 1.85 millimeter CAMM connectors in the illustrated embodiments).

Furthermore, the connection of the secondary circuit board 406 to the primary circuit board bottom surface 404a of the primary circuit board 404 via a circuit board connector (i.e., a 1.85 millimeter LGA connector in the illustrated embodiments) increases the height of the volume of the card component envelope “below” the primary circuit board bottom surface 404a by an amount that is sufficient to allow memory devices (i.e., CAMM devices in the illustrated embodiments) to be provided on the primary circuit board bottom surface 404a of the primary circuit board 404 using relatively higher-profile memory device connectors (i.e., 2.85 millimeter CAMM connectors in the illustrated embodiments), which one of skill in the art in possession of the present disclosure will appreciate may increase an airflow gap between the primary circuit board 404 and the memory devices 414a and 416a to provide enhanced cooling.

However, while specific examples of increasing the height of the volume of the card component envelope “below” a circuit board bottom surface of a circuit board in a computing device card system has been described for the purpose of providing memory subsystems (e.g., CAMM devices) on that circuit board bottom surface such that they fit within that card component envelope, one of skill in the art in possession of the present disclosure will appreciate how the techniques described herein for increasing the height of the volume of the card component envelope “below” a circuit board bottom surface of a circuit board in a computing device card system may be utilized to provide any of a variety of components on that circuit board bottom surface such that they fit within that card component envelope while remaining within the scope of the present disclosure as well.

Furthermore, one of skill in the art in possession of the present disclosure will appreciate how providing the connectors 408a-408f (e.g., PMM connectors) on the secondary circuit board 406 allows the thickness of the primary circuit board 404 to be increased relative to the circuit board 204 in the conventional card system 200 discussed above with reference to FIGS. 2A and 2B (i.e., inclusion of the connectors 206a-206f on the circuit board 204 in the conventional card system 200 discussed above with reference to FIGS. 2A and 2B operates to limit the thickness of the circuit board 204 to that required to provide those connectors 206, and thus limits the layer count in the circuit board 204). As such, the primary circuit board 404 in the computing device card system 400 may be provided with an increased thickness relative to the circuit board 204 in the conventional card system 200 in order to increase routing channels, power delivery, circuit board stiffness, and/or provide other circuit board benefits known in the art without modifying the thickness of the multi-connector edge 408 on the secondary circuit board 406 in order to maintain compatibility with computing device card connectors.

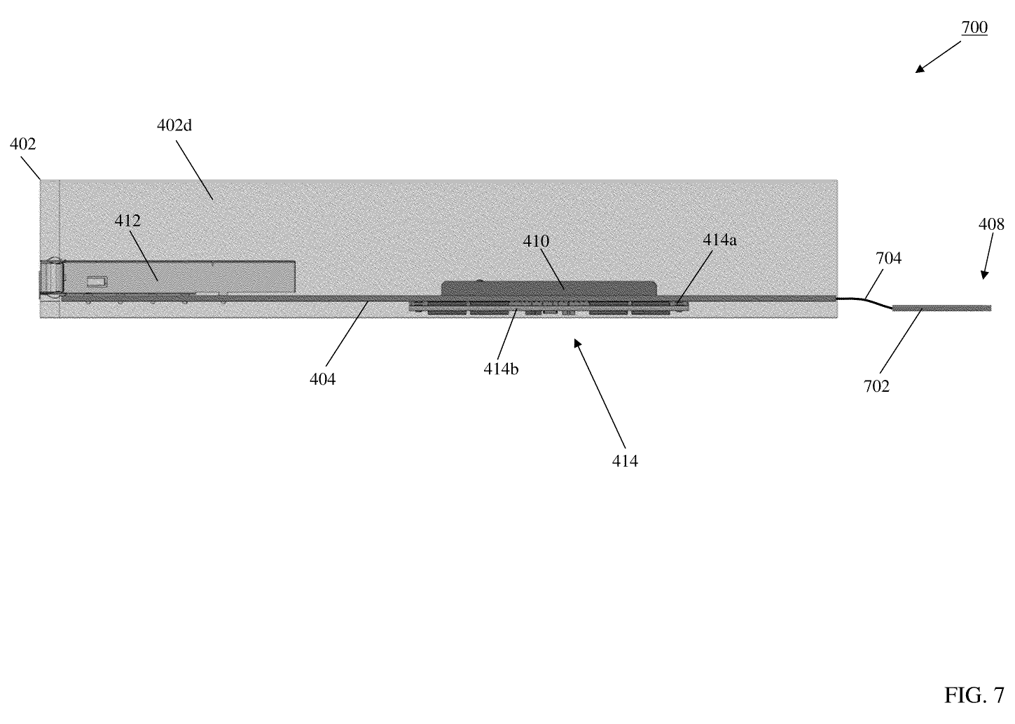

However, while specific structures have been illustrated and described for “offsetting” a secondary circuit board from a primary circuit board in order to provide the benefits discussed above, one of skill in the art in possession of the present disclosure will appreciate how the secondary circuit board of the present disclosure may be configured to be offset from the primary circuit board of the present disclosure in a variety of manners that will fall within the scope of the present disclosure. For example, with reference to FIG. 7, a computing device card system 700 is illustrated that is similar to the computing device card system 400 discussed above with reference to FIGS. 4A-4D, with similar elements provided with similar element numbers.

As will be appreciated by one of skill in the art in possession of the present disclosure, in the computing device card system 700, the secondary circuit board 406 and its connection to the primary circuit board 404 via the circuit board connection subsystem 407 discussed above with reference to FIGS. 4A-4D is replaced with a secondary circuit board 702 that includes the multi-connector edge 408 discussed above, and that is moveably coupled to the primary circuit board by a flex cable 704 or other primary circuit board/secondary circuit board connector that one of skill in the art in possession of the present disclosure would recognize as allowing the relative movement of the secondary circuit board 406 and the primary circuit board 404 discussed below.

Similarly as described above, one of skill in the art in possession of the present disclosure will appreciate how the card component envelope for the computing device card system 700 is based on the multi-connector edge 408 and its connectors 408a-408f, and the flex cable 704 allows relative movement between the computing device card system 700 and the multi-connector edge 408, and thus allows positioning of the computing device card system 700 in the computing device such that it does not interfere with computing device components in the computing device when the multi-connector edge 408 is connected to a card connector on a computing device (discussed in further detail below). As such, the height of the volume of the card component envelope “below” the primary circuit board bottom surface 404b of the primary circuit board 404 in the computing device card system 700 may be configured as needed to allow components to be provided on the primary circuit board bottom surface 404b while fitting within that card component envelope, with the secondary circuit board 700 moveable relative to the primary circuit board 404 to connect to available card connectors in a computing device.

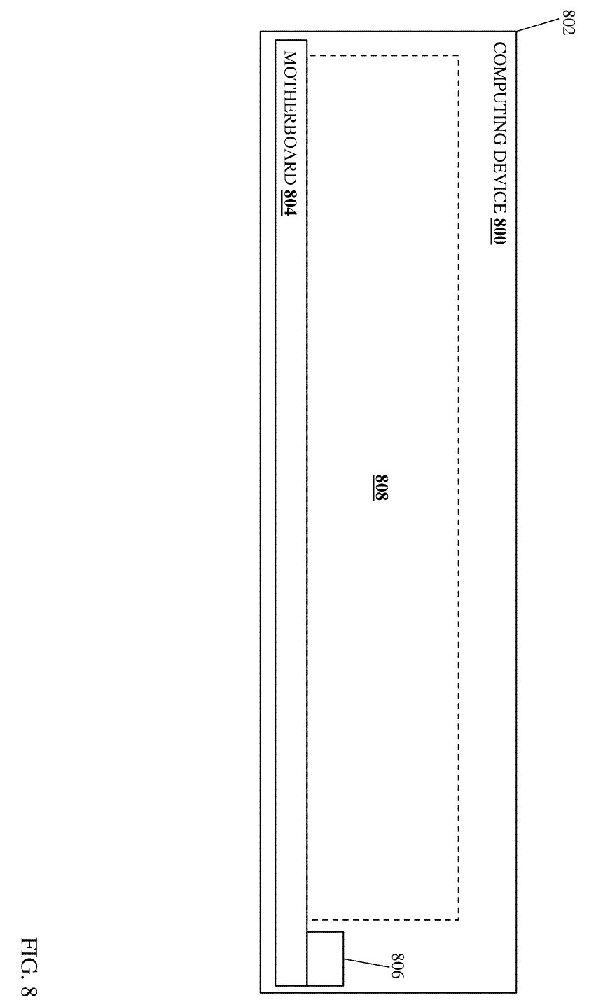

With reference to FIG. 8, an embodiment of a computing device 800 is illustrated that may be used with the computing device card system of the present disclosure. In an embodiment, the computing device 800 may be provided by the IHS 100 discussed above with reference to FIG. 1, and/or may include some or all of the components of the IHS 100, and in specific examples may be provided by a server device. However, while described as being provided by a server device, one of skill in the art in possession of the present disclosure will appreciate how the computing device 800 may be provide by any of a variety of computing devices while remaining within the scope of the present disclosure as well. In the illustrated embodiment, the computing device 800 includes a chassis 802 that houses the components of the computing device 800, only some of which are illustrated and described below. In the illustrated example, the chassis 802 houses a motherboard 804 that supports the components of the computing device 800, and in the illustrated embodiment a card connector 806 is mounted to the motherboard 804. Furthermore, the chassis 802 defines a card system housing 808 that is located adjacent the motherboard 804 and the card connector 806. However, while a specific computing device 800 has been illustrated and described, one of skill in the art in possession of the present disclosure will appreciate how computing devices used with the computing device card system of the present disclosure may include variety of components and/or configurations while remaining within the scope of the present disclosure as well.

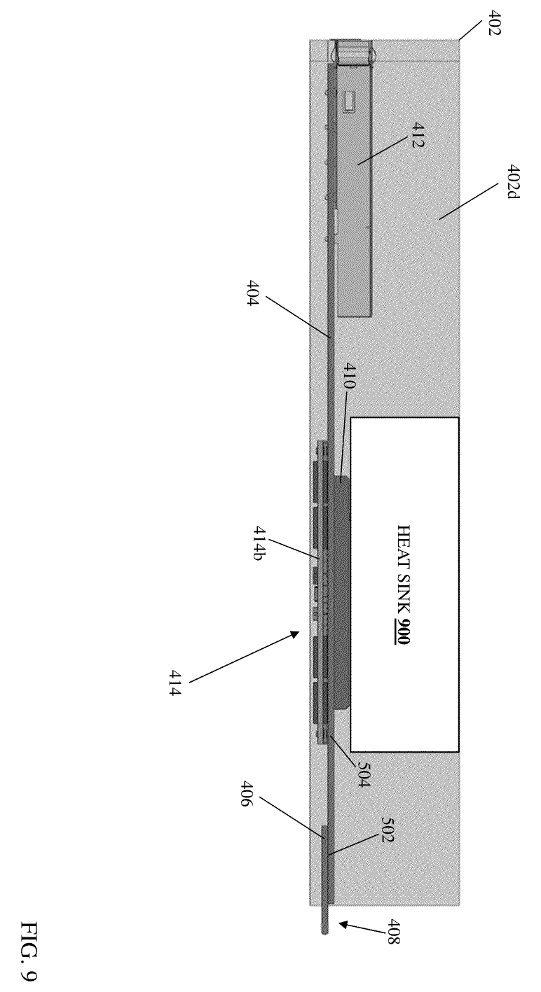

With reference to FIG. 9, a heat sink 900 may be coupled to the processing system 410 on the computing device card system 500 discussed above with reference to FIG. 5 using any of a variety of heat sink coupling techniques known in the art, and one of skill in the art in possession of the present disclosure will appreciate how the heat sink 900 may be coupled to the processing system 410 on the computing device card systems 600 and 700 in a similar manner. As described above, the heat sink 900 may span the width of the primary circuit board 404 between the side walls 402c and 402d of the chassis 402.

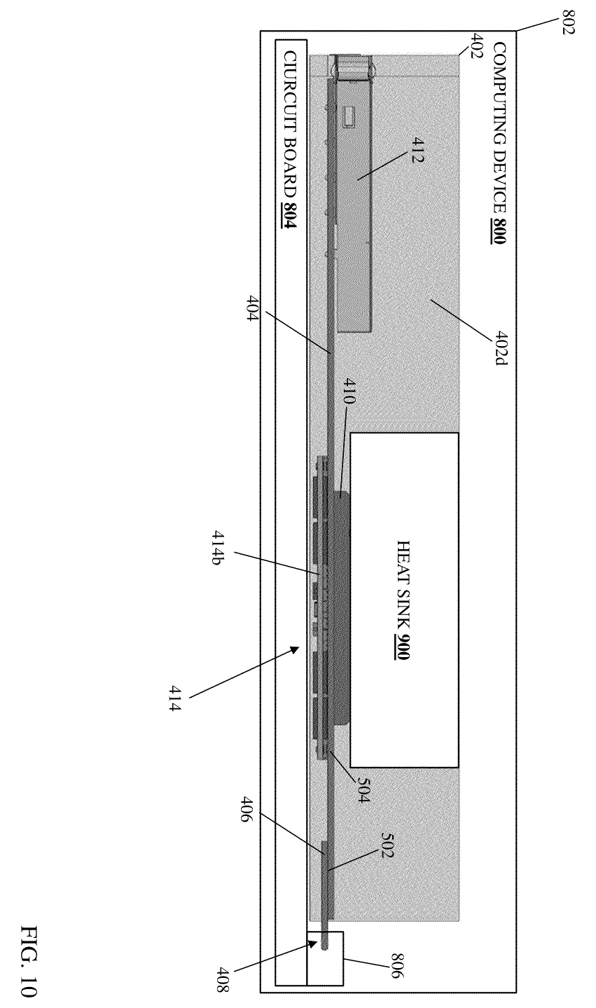

With reference to FIG. 10, the computing device card system 500 may then be positioned in the card system housing 808 defined by the chassis 802 of the computing device 800 such that the connectors 408a-408f on the multi-connector edge 408 of the secondary circuit board 406 engage the card connector 806 on the motherboard 404, and one of skill in the art in possession of the present disclosure will appreciate how the computing device card systems 600 and 700 may be provided in the computing device 800 in a similar manner. As will be appreciated by one of skill in the art in possession of the present disclosure, the positioning of the memory subsystem 414 (and the memory subsystem 416, not visible in FIG. 10) within the card component envelope of the computing device card system 500 (or within the card component envelopes of the computing device card systems 600 and 700) prevents the computing device card system 500 (or the computing device card systems 600 and 700) from interfering with any other computing device components in the chassis 802 of the computing device 800.

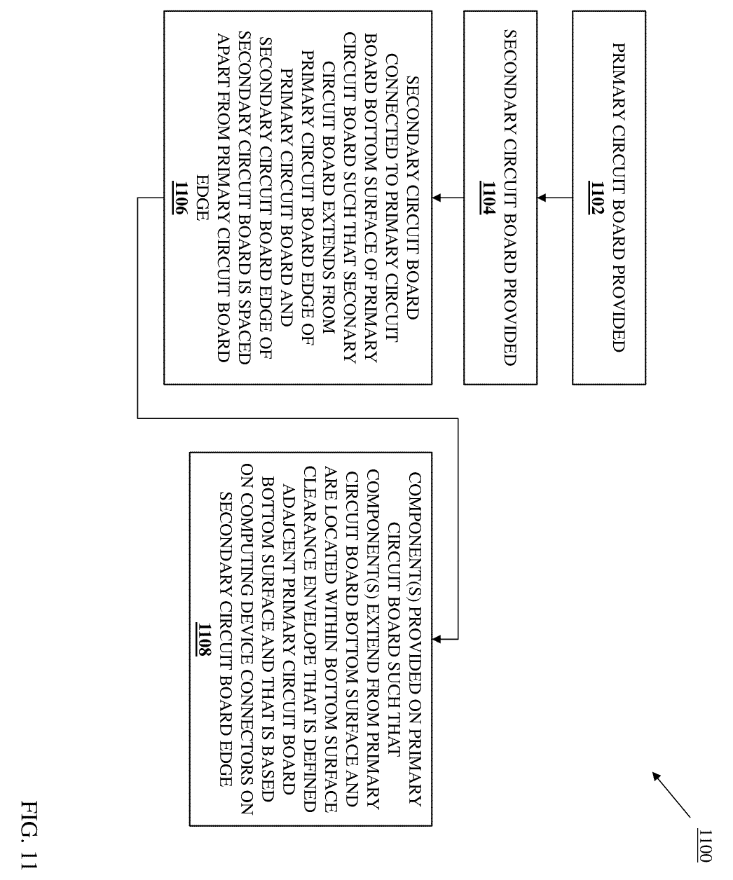

Referring now to FIG. 11, an embodiment of a method 1100 for providing a card component envelope for a card system used with a computing device is illustrated. As discussed below, the systems and methods of the present disclosure provide for the configuration of card systems to define card component envelopes that allow components to be provided on cards in those card systems such that they fit within those card component envelopes. For example, the computing device card system of the present disclosure may include a primary circuit board having an opposing primary circuit board top surface and bottom surface with an edge between them. A secondary circuit board includes an opposing secondary circuit board top surface and bottom surface with an edge between them. The secondary circuit board is connected to the primary circuit board bottom surface, and the secondary circuit board edge includes computing device connectors. The secondary circuit board extends from the primary circuit board edge such that the secondary circuit board edge is spaced apart from the primary circuit board edge. A bottom surface component envelope is defined adjacent the primary circuit board bottom surface and is based on the computing device connectors. Bottom surface component(s) extends from the primary circuit board bottom surface and are located within the bottom surface component envelope. As such, computing device card systems with card component envelopes that would otherwise not allow particular components to be used with those computing devices card systems may be reconfigured to allow the use of those components with those computing device card systems.

The method 1100 begins at block 1102 where a primary circuit board is provided. In an embodiment, at block 1102, the primary circuit board 404 discussed above with reference to FIGS. 4A-4D, 5A and 5B, 6A and 6B, or 7 may be provided that includes the primary circuit board top surface 404a, the primary circuit board bottom surface 404b, and the primary circuit board edge 404c. As will be appreciated by one of skill in the art in possession of the present disclosure, the primary circuit board 404 may be manufactured with particular dimensions (e.g., the PMM dimensions described above), and may include (or may be configured to support) any of a variety of components (e.g., the processing system 410, the networking device 412, and the memory subsystems 414 and 416 described above), as well as any circuit board connection subsystem features that one of skill in the art in possession of the present disclosure would recognize as allowing its connection to the secondary circuit board as described below.

The method 1100 then proceeds to block 1104 where a secondary circuit board is provided. In an embodiment, at block 1104, the secondary circuit board 406 discussed above with reference to FIGS. 4A-4D, 5A and 5B, or 6A and 6B may be provided that includes the secondary circuit board top surface 406a, the secondary circuit board bottom surface 406b, and the secondary circuit board edge 406c, with the multi-connector edge 408 extending from the secondary circuit board edge 406c and including the connectors 408a-408f. Furthermore, as discussed above with reference to FIG. 7, in other embodiments of block 1104 the secondary circuit board 700 may be provided that includes the multi-connector edge 408 having the connectors 408a-408f. As will be appreciated by one of skill in the art in possession of the present disclosure, the multi-connector edge 408 and connectors 408a-408f on the secondary circuit board 404 may be manufactured according to particular specifications (e.g., the PMM specifications described above), and may include any circuit board connection subsystem features that one of skill in the art in possession of the present disclosure would recognize as allowing its connection to the primary circuit board as described below

The method 1100 then proceeds to block 1106 where the secondary circuit board is connected to the primary circuit board bottom surface of the primary circuit board such that the secondary circuit board extends from a primary circuit board edge of the primary circuit board and a secondary circuit board edge of the secondary circuit board is spaced apart from the primary circuit board edge. In an embodiment, at block 1106, the secondary circuit board 406 discussed above may be connected to the primary circuit board 404 discussed above via the circuit board connection subsystem 407 described above with reference to FIGS. 4A-4D, the circuit board direct connection subsystem 502 described above with reference to FIGS. 5A and 5B, or the circuit board connector subsystem 602 described above with reference to FIGS. 6A and 6B. Furthermore, as discussed above with reference to FIG. 7, in other embodiments of block 1106 the secondary circuit board 700 may be connected to the primary circuit board 404 via the flex cable 702 using any of a variety of circuit board/flex cable connection techniques that would be apparent to one of skill in the art in possession of the present disclosure.

The method 1100 then proceeds to block 1108 where one or more components are provided on the primary circuit board such that the one or more components extend from the primary circuit board bottom surface and are located within a bottom surface component envelope that is defined adjacent the primary circuit board bottom surface and that is based on computing device connectors on the secondary circuit board edge. In an embodiment, at block 1108, the memory subsystems 414 and 416 may be provided on the primary circuit board 404 such that those memory subsystems 414 and 416 extend from the primary circuit board bottom surface 404b and are located within the height of the volume of the card component envelope “below” the primary circuit board bottom surface 404b, as illustrated in FIGS. 4A-4D, 5A and 5B, 6A and 6B, and 7. For example, at block 1108 the memory devices 414b and 416b may be connected to the memory device connectors 414a and 416a that are mounted to the primary circuit board bottom surface 404b.

Thus, systems and methods have been described that provide for the configuration of card systems to define card component envelopes that allow components to be provided on those card systems such that they fit within those card component envelopes. For example, the computing device card system of the present disclosure may include a primary circuit board having an opposing primary circuit board top surface and bottom surface with an edge between them. A secondary circuit board includes an opposing secondary circuit board top surface and bottom surface with an edge between them. The secondary circuit board is connected to the primary circuit board bottom surface, and the secondary circuit board edge includes computing device connectors. The secondary circuit board extends from the primary circuit board edge such that the secondary circuit board edge is spaced apart from the primary circuit board edge. A bottom surface component envelope is defined adjacent the primary circuit board bottom surface and is based on the computing device connectors. Bottom surface component(s) extends from the primary circuit board bottom surface and are located within the bottom surface component envelope. As such, computing device card systems with card component envelopes that would otherwise not allow particular components to be used with those computing devices card systems may be reconfigured to allow the use of those components with those computing device card systems.

Although illustrative embodiments have been shown and described, a wide range of modification, change and substitution is contemplated in the foregoing disclosure and in some instances, some features of the embodiments may be employed without a corresponding use of other features. Accordingly, it is appropriate that the appended claims be construed broadly and in a manner consistent with the scope of the embodiments disclosed herein.

What is claimed is:

1. A computing device card system, comprising:
a primary circuit board that includes a primary circuit board top surface, a primary circuit board bottom surface that is located opposite the primary circuit board from the primary circuit board top surface, and a primary circuit board edge that extends between the primary circuit board top surface and the primary circuit board bottom surface;
a secondary circuit board that is connected to the primary circuit board bottom surface and that includes a secondary circuit board top surface, a secondary circuit board bottom surface that is located opposite the secondary circuit board from the secondary circuit board top surface, and a secondary circuit board edge that extends between the secondary circuit board top surface and the secondary circuit board bottom surface and includes a plurality of computing device connectors, wherein the secondary circuit board extends from the primary circuit board edge such that the secondary circuit board edge is spaced apart from the primary circuit board edge;
a bottom surface component envelope that is defined adjacent the primary circuit board bottom surface and that is based on the plurality of computing device connectors included on the secondary circuit board edge; and
at least one bottom surface component that extends from the primary circuit board bottom surface and that is located within the bottom surface component envelope.

2. The system of claim 1, wherein the plurality of computing device connectors are Pluggable Multipurpose Module (PMM) connectors.

3. The system of claim 1, wherein the plurality of computing device connectors are Peripheral Component Interconnect express (PCIe) Card ElectroMechanical (CEM) connectors.

4. The system of claim 1, wherein the least one bottom surface component includes at least one Compression Attached Memory Module (CAMM) component.

5. The system of claim 1, wherein the secondary circuit board is directly connected to the primary circuit board.

6. The system of claim 1, wherein the secondary circuit board is connected to the primary circuit board by a connector subsystem that is mounted to at least one of the primary circuit board and the secondary circuit board.

7. An Information Handling System (IHS), comprising:
a chassis;
a card connector that is housed in the chassis; and
a card that is connected to the card connector, wherein the card includes:
a primary circuit board that includes a primary circuit board top surface, a primary circuit board bottom surface that is located opposite the primary circuit board from the primary circuit board top surface, and a primary circuit board edge that extends between the primary circuit board top surface and the primary circuit board bottom surface;
a secondary circuit board that is connected to the primary circuit board bottom surface and that includes a secondary circuit board top surface, a secondary circuit board bottom surface that is located opposite the secondary circuit board from the secondary circuit board top surface, and a secondary circuit board edge that extends between the secondary circuit board top surface and the secondary circuit board bottom surface and includes a plurality of computing device connectors that engage the card connector, wherein the secondary circuit board extends from the primary circuit board edge such that the secondary circuit board edge is spaced apart from the primary circuit board edge;
a bottom surface component envelope that is defined adjacent the primary circuit board bottom surface and that is based on the plurality of computing device connectors included on the secondary circuit board edge; and
at least one bottom surface component that extends from the primary circuit board bottom surface and that is located within the bottom surface component envelope.

8. The IHS of claim 7, wherein the card connector and the plurality of computing device connectors are Pluggable Multipurpose Module (PMM) connectors.

9. The IHS of claim 7, wherein the card connector and the plurality of computing device connectors are Peripheral Component Interconnect express (PCIe) Card ElectroMechanical (CEM) connectors.

10. The IHS of claim 7, wherein the least one bottom surface component includes at least one Compression Attached Memory Module (CAMM) component.

11. The IHS of claim 7, wherein the secondary circuit board is directly connected to the primary circuit board.

12. The IHS of claim 7, wherein the secondary circuit board is connected to the primary circuit board by a connector subsystem that is mounted to at least one of the primary circuit board and the secondary circuit board.

13. The IHS of claim 7, further comprising:
a top surface component envelope that is located adjacent the primary circuit board top surface and that is based on the plurality of computing device connectors included on the secondary circuit board edge; and
at least one top surface component that extends from the primary circuit board top surface and that is located within the top surface component envelope.

14. A method for providing a card component envelope for a card system used with a computing device, comprising:
providing a primary circuit board that includes a primary circuit board top surface, a primary circuit board bottom surface that is located opposite the primary circuit board from the primary circuit board top surface, and a primary circuit board edge that extends between the primary circuit board top surface and the primary circuit board bottom surface;
providing a secondary circuit board that includes a secondary circuit board top surface, a secondary circuit board bottom surface that is located opposite the secondary circuit board from the secondary circuit board top surface, and a secondary circuit board edge that extends between the secondary circuit board top surface and the secondary circuit board bottom surface and includes a plurality of computing device connectors;
connecting the secondary circuit board to the primary circuit board bottom surface such that the secondary circuit board extends from the primary circuit board edge and the secondary circuit board edge us spaced apart from the primary circuit board edge; and
providing, on the primary circuit board, at least one bottom surface component that extends from the primary circuit board bottom surface and is located within a bottom surface component envelope that is defined adjacent the primary circuit board bottom surface and that is based on the plurality of computing device connectors included on the secondary circuit board edge.

15. The method of claim 14, wherein the plurality of computing device connectors are Pluggable Multipurpose Module (PMM) connectors.

16. The method of claim 14, wherein the plurality of computing device connectors are Peripheral Component Interconnect express (PCIe) Card ElectroMechanical (CEM) connectors.

17. The method of claim 14, wherein the least one bottom surface component includes at least one Compression Attached Memory Module (CAMM) component.

18. The method of claim 14, further comprising:
directly connecting the secondary circuit board to the primary circuit board.

19. The method of claim 14, further comprising:
connecting, via a connector subsystem that is mounted to at least one of the primary circuit board and the secondary circuit board, the secondary circuit board to the primary circuit board.

20. The method of claim 14, further comprising:
providing, on the primary circuit board, at least one top surface component that extends from the primary circuit board top surface and is located within a top surface component envelope that is defined adjacent the primary circuit board top surface and that is based on the plurality of computing device connectors included on the secondary circuit board edge.
